(19) United States
(12) Patent Application Publication
(10) Pub. No.: US 2012/0038426 A1
(43) Pub. Date: Feb. 16, 2012

(54) PLL FREQUENCY SYNTHESIZER, WIRELESS COMMUNICATION APPARATUS AND PLL FREQUENCY SYNTHESIZER CONTROLLING METHOD

(76) Inventors: Masahisa TAMURA, Kanagawa (JP); Tatsuo Maeda, Kanagawa (JP)

(21) Appl. No.: 13/198,298

(22) Filed: Aug. 4, 2011

(30) Foreign Application Priority Data
Aug. 11, 2010 (JP) 2010-180316

(51) Int. Cl. H03L 7/18

(52) U.S. Cl. 331/25

(57) ABSTRACT

There is provided a PLL frequency synthesizer including a phase comparing unit, a current pulse signal generating unit, an converting unit which converts the current pulse signal from the current pulse signal generating unit into a voltage signal, an outputting unit which outputs a signal of an oscillation frequency matching the voltage signal from the converting unit, a divider which divides an output from the outputting unit by a division ratio matching a division ratio control signal to output as the division signal, a division ratio control signal generating unit which generates the division ratio control signal based on division ratio data for fractional-N, and the phase error compensation signal generating unit which generates at least two items of phase error compensation data from the division ratio data, and generates the phase error compensation signal utilizing the at least two generated items of phase error compensation data at different timings.

### BACKGROUND

The present disclosure relates to a PLL frequency synthesizer, a wireless communication apparatus and a PLL frequency synthesizer controlling method, and more particularly to a fractional-N PLL frequency synthesizer which can multiply a reference frequency with a non-integral conversion coefficient.

For wireless communication apparatuses and broadcasting equipment, a PLL (Phase Locked Loop) frequency synthesizer which has a PLL circuit is generally used as a local oscillator of a frequency converter (mixer).

As an example of the PLL circuit, an integer-N PLL circuit inputs a signal obtained by dividing a reference frequency signal from a reference oscillation source and a signal obtained by dividing a frequency signal from a voltage controlling oscillator (VCO), to a phase comparator to perform a phase lock operation. Hence, the oscillation frequency of the VCO is regarded as the frequency which is an integral multiple of a comparison frequency input to the phase comparator.

This means that, if channel steps necessary in a wireless communication system is segmentalized more, the comparison frequency needs to be set low. Generally, when the comparison frequency is set lower, the time (lockup time) necessary to switch channels increases, and therefore the comparison frequency and lockup time hold the trade-off relationship. Further, in terms of noise performance, it is preferable to set the comparison frequency as high as possible and reduce the division ratio N as low as possible. That is, the comparison frequency and noise performance hold the trade-off relationship.

As the technique of canceling the trade-offs, fractional-N PLL is known which enables an operation in smaller channel steps than the comparison frequency. Further, as one method of implementing this fractional-N PLL, a technique using a delta sigma modulator is known.

The delta sigma modulator employs a configuration of integrating input signals and quantizing the signals with one bit or multi-bits, and is applied to, for example, an A/D (analog/digital) converter, a D/A (digital/analog) converter and a PLL circuit.

Here, the transfer function with respect to quantization noise of the delta sigma modulator is small in a low frequency area and high in a high frequency area. That is, with the delta sigma modulator, a quantization noise component of an output signal concentrates on the high frequency area, and therefore an output signal including a suppressed noise component in a band can be acquired. This noise component suppressing effect is generally referred to as “noise shaping”.

FIG. 12 is a block diagram schematically illustrating a configuration of a fractional-N PLL frequency synthesizer in the related art disclosed in U.S. Pat. No. 6,960,947.

In FIG. 12, the phase comparator 1101 receives an input of a reference frequency signal REFCLK. The phase comparator 1101 compares the phase of a division signal DIVCLK obtained by dividing an output signal VCOCLK of a voltage controlling oscillator (VCO) 1104 of a later stage by N by means of a divider 1105, and the phase of the reference frequency signal REFCLK. When the phase (edge) of the reference frequency signal REFCLK is preceding, an UP signal output of the phase comparator 1101 is a high level until the phase (edge) of the delaying division signal DIVCLK arrives. When the phase (edge) of the division signal (DIVCLK) arrives, the phase comparator 1101 is reset, the UP signal output becomes a low level. By contrast with this, when the phase (edge) of the division signal (DIVCLK) is preceding, a DN (down) signal output of the phase comparator 1101 is a high level until the phase (edge) of a delaying reference frequency signal REFCLK arrives. When the phase (edge) of the reference frequency signal REFCLK arrives, the phase comparator 1101 is reset and the DN signal output becomes a low level. The signal output from the phase comparator 1101 is output to a charge pump 1102.

The charge pump 1102 causes an inflow and outflow of the current matching the UP signal and DN signal from the phase comparator 1101 to generate a current pulse signal I_{CP} proportional to the phase difference. The current pulse signal I_{CP} of the charge pump 1102 is output to a loop filter 1103.

The loop filter 1103 integrates, smoothes and converts the current pulse signal I_{CP} of the charge pump 1102 into a voltage signal. An output voltage signal VT of this loop filter 1103 serves as a control voltage for the VCO 1104.

The VCO 1104 outputs the signal VCOCLK of an oscillation frequency matching the output voltage signal VT from the loop filter 1103. This output signal VCOCLK is output to a configuration (for example, frequency modulator) at a later stage (not illustrated) as an output signal of the fractional-N PLL frequency synthesizer, divided by the divider 1105 and then is fed back to the phase comparator 1101.

The delta sigma modulator 1107 integrates fractional data K of the division ratio supplied from a data supplying means such as a register (not illustrated), quantizes the fractional data K and outputs an output signal X to an adder 1106. The output signal X of the delta sigma modulator 1107 is a sequence represented by a pseudo random integer where an average value of the output signal X is equal to an input value K/M (M is the bit depth of K), and a sequence pattern is determined based on an order, bit width and input value of the delta sigma modulator 1107. The adder 1106 adds the output signal X of the delta sigma modulator 1107 to integer data N of the division ratio supplied from the data supplying means, and supplies the division ratio control signal N+X to the divider 1105. That is, the division ratio control signal N+X is a pseudo random integer sequence where the average value is equal to N+K/M.

The divider 1105 is a programmable divider which can adopt a plurality of division ratios according to supplied data, receives the modulated division ratio control signal N+X, and divides the output signal VCOCLK at a division ratio matching the division ratio control signal N+X.

Thus, the fractional-N PLL frequency synthesizer illustrated in FIG. 12 modulates the divider 1105 which divides the output of the VCO 1104 according to an output signal of the delta sigma modulator 1107 to realize fractional-N on average.

Generally, with a fractional-N PLL frequency synthesizer, although the phase of the reference frequency signal REFCLK and the phase of the division signal DIVCLK match in the phase comparator 1101 on average, both the phases do not completely match. Therefore, the UP signal or DN signal is output per phase comparison, and the charge pump 1102 performs a current inflow or outflow operation. As a result, the output voltage signal VT which is a control voltage for the VCO 1104 is modulated and the frequency of the output signal VCOCLK is further modulated. Although the modulation component concentrates on a high frequency area due to noise shaping by the delta signal modulator 1107 and therefore can be suppressed by the loop filter 1103, the band of the loop filter 1103 needs to be relatively narrowed compared to the band of the loop filter of the integer-N PLL frequency synthesizer to effectively suppress the modulation component, and therefore it is difficult to sufficiently take an advantage of the fractional-N PLL frequency synthesizer of an increased comparison frequency.

To solve this issue, U.S. Pat. No. 6,960,947 discloses a method of canceling an instantaneous phase error output from the phase comparator 1101 of the fractional-N PLL frequency synthesizer using the D/A (digital/analog) converter 1109.

This will be described with reference to FIG. 12. Quantization noise output from the delta sigma modulator 1107 is determined based on the order, bit width and input value, so that the instantaneous phase error produced in the phase comparator 1101 can be predicted. The instantaneous phase error is calculated according to the following equation 1 when the cycle of the reference frequency signal REFCLK is 27c.

$$Δ φ [ n ] = Δ φ [ n - 1 ] + 2 \cdot π ( \frac{K - M \cdot X [ n ]}{M \cdot N + K} ) \qquad equation 1$$

Here, n is a natural number, K is fractional data of the division ratio, M is the bit depth of the fractional data K, N is integer data of the division ratio and X is an output signal of the delta sigma modulator 1107.

Based on above equation 1, the controlling unit 1108 integrates the difference between fractional data K and the output signal X of the delta sigma modulator 1107, and scales this difference at the division ratio to supply an instantaneous phase error compensation signal APER to the D/A converter 1109.

The D/A converter 1109 is, for example, a current output D/A converter, and adds a phase error compensation current pulse signal I_{DAC} having the time width related to the cycle of the reference frequency signal REFCLK, to a current pulse signal I_{CP} which is the output of the charge pump 1102. The charge amount supplied by the phase error compensation current pulse signal I_{DAC} is equal to the absolute value of the charge amount supplied by the current pulse signal I_{CP} which is the output of the charge pump 1102, and has the opposite polarity. Hence, the charge amount which flows in or flows out from the loop filter 1103 becomes zero. As a result, fluctuation of the output voltage signal VT which is a control voltage for the VCO 1104 can be suppressed, so that it is possible to expand the band width of the loop filter 1103 and take an advantage of the fractional-N PLL frequency synthesizer.

By the way, the fractional-N PLL frequency synthesizer needs to accurately convert a little phase difference into a current pulse irrespectively of whether or not the instantaneous phase error compensation function is provided, and therefore it is important that the phase comparator including a charge pump has a high linearity to provide good phase noise performance.

A well-known non-linearity of the phase comparator includes (1) gain discontinuity (dead zone and gain excessiveness) near zero of the phase difference and (2) mismatch between the UP current and DN current. These can be avoided by locking the PLL circuit in a state where the PLL circuit has a constant phase difference, that is, by shifting the operation point of the phase comparator to a linear area.

U.S. Pat. No. 4,970,475 discloses a method of shifting the operation point of the phase comparator to a linear area.

FIG. 13 is a block diagram schematically illustrating a configuration of a phase comparator including a charge pump disclosed in U.S. Pat. No. 4,970,475. FIG. 14 is a timing chart of each signal in the phase comparator in FIG. 13.

A method of improving the linearity of the phase comparator will be described with reference to the block diagram of the phase comparator illustrated in FIG. 13 and the timing chart illustrated in FIG. 14.

With the phase (edge) of the division signal DIVCLK, a flip-flop 1202 is set and the DN signal becomes a high level. A current source 1206 is activated according to the DN signal, and a current Idown is extracted from a loop filter (not illustrated).

With the phase (edge) of the reference frequency signal REFCLK, the flip-flop 1201 is set, and the UP signal becomes a high level. A current source 1205 is activated according to the UP signal, and a current Iup is supplied to a loop filter (not illustrated). At this time, the input of an AND gate 1203 is a high level, and therefore a high level is output to an output R2 and the flip-flop 1202 is reset.

The output R2 of the AND gate 1203 is connected to a delay circuit 1204. Therefore, the flip-flop 1201 is reset after the phase of the reference frequency signal REFCLK arrives and a delay time Tdly of the delay circuit 1204 passes.

The PLL circuit settles in a state where the charge input and output to and from the loop filter becomes zero, and therefore the phase of the division signal DIVCLK in a stationary state precedes by the time equal to the delay time Tdly of the delay circuit 1204 compared to the phase of the reference frequency signal REFCLK. By selecting a greater delay time Tdly of the delay circuit 1204 than a dynamic range of an instantaneous phase error resulting from the fractional-N operation, it is possible to shift an operation point of the phase comparator to a linear area and provide a fractional-N PLL frequency synthesizer of good phase noise performance.

### SUMMARY

With a instantaneous phase error compensating method of a fractional-N PLL frequency synthesizer in the related art, the phase error compensation current pulse signal I_{DAC} output from the D/A converter 1109 has the time width related to the cycle of the reference frequency signal REFCLK, and therefore needs to be scaled according to (M*N+K) as shown in the equation 1. Mounting a divider in a logical circuit leads to a nonnegligible increase in a circuit scale, thereby making mounting economically difficult. Further, although it is proposed that scaling according to (M*N+K) is approximated using M*N, this produces an error in a phase error compensating operation. This error tends to be accumulated in a long cycle in many cases, and has a risk of deterioration such as intolerable noise in the PLL band.

Further, it is proposed that the controlling portion 1108 rounds lower bits of the instantaneous phase error compensation signal APER or a delta sigma modulator (not illustrated) processes the lower bits to reduce the number of bits necessary in the D/A converter 1109. A configuration is employed which adds information of the processed lower bits to upper bits, and therefore this addition increases the number of bits (gradation) necessary in the D/A converter 1109.

Further, as described above, the phase error compensation current pulse signal I_{DAC} output from the D/A converter 1109 has the time width related to the cycle of the reference frequency signal REFCLK. To supply a little charge amount necessary for compensation using a pulse having a long time width compared to a little phase error to be compensated for, the current amplitude of the phase error compensation current pulse signal I_{DAC} needs to be decreased. That is, the D/A converter 1109 is necessary to provide very high resolution. Even though a device is made to reduce the number of bits in the D/A converter 1109, mounting a highly-precise analog circuit increases cost.

Further, the amplitude of the phase error compensation current pulse signal I_{DAC} is related to the amplitude of the current pulse signal I_{CP} which is the output of the charge pump 1102, and therefore, by increasing the current pulse signal I_{CP} which is the output of the charge pump 1102, it is possible to relax the demand for resolution of the D/A converter 1109. However, to obtain the same loop characteristics under this condition, it is necessary to increase the capacity of the loop filter 1103. This makes it difficult to mount the loop filter 1103 on an integrated circuit.

A linearity improving method of a phase comparator in the related art determines an operation point shift amount of the phase comparator by means of the delay circuit 1204, and has a concern that accumulation of jitter deteriorates phase noise.

Further, the delay amount of the delay circuit 1204 significantly fluctuates due to fluctuation of semiconductor process, temperature and power source voltage. Even under the condition in which the delay amount is minimum, a design is necessary where sufficient delay is provided to cover a dynamic range of an instantaneous phase error resulting from the fractional-N operation. However, as a result, an excessive delay amount is given under a Typcal condition or a condition where the delay amount is maximum. Hence, the influence of current noise of the charge pump becomes significant in addition to an increase in the influence of jitter, thereby causing deterioration of phase noise. Further, when the delay time is longer more than necessary, the voltage of the loop filter more significantly fluctuates upon phase comparison, thereby increasing a reference spurious.

In light of the foregoing, it is desirable to provide a novel and improved PLL frequency synthesizer, wireless communication apparatus and PLL frequency synthesizer controlling method which can be configured at low cost and can improve performance.

According to an embodiment of the present disclosure, there is provided a PLL frequency synthesizer including a phase comparing unit which compares a phase of a reference frequency signal and a phase of a division signal, a current pulse signal generating unit which generates a current pulse signal according to a signal from the phase comparing unit and a phase error compensation signal from a phase error compensation signal generating unit, an converting unit which converts the current pulse signal from the current pulse signal generating unit into a voltage signal, an outputting unit which outputs a signal of an oscillation frequency matching the voltage signal from the converting unit, a divider which divides an output from the outputting unit by a division ratio matching a division ratio control signal to output as the division signal, a division ratio control signal generating unit which generates the division ratio control signal based on division ratio data for fractional-N, and the phase error compensation signal generating unit which generates at least two items of phase error compensation data from the division ratio data, and generates the phase error compensation signal utilizing the at least two generated items of phase error compensation data at different timings.

The phase error compensation signal generating unit may include an adding unit which adds a fixed value to the phase error compensation data.

The phase error compensation signal generating unit may include a thermometer code converting unit which converts the phase error compensation data from binary code into thermometer code.

The phase error compensation signal generating unit may include a randomizing unit which randomizes an order to use the phase error compensation data.

According to an embodiment of the present disclosure, there is provided a wireless communication apparatus including the PLL frequency synthesizer.

According to an embodiment of the present disclosure, there is provided a PLL frequency synthesizer controlling method including omparing a phase of a reference frequency signal and a phase of a division signal, generating a current pulse signal according to a signal generated in the phase comparing step and a phase error compensation signal generated in a phase error compensation signal generating step, converting the current pulse signal generated in the current pulse signal generating step into a voltage signal, outputting a signal of an oscillation frequency according to the voltage signal generated in the converting step, dividing an output of the outputting step by a division ratio matching a division ratio control signal to output as the division signal, generating the division ratio control signal based on division ratio data for fractional-N, and generating at least two items of phase error compensation data from the division ratio data, and generating the phase error compensation signal utilizing the at least two generated items of phase error compensation data at different timings.

As described above, the disclosure can be configured at low cost and can improve performance.

### BRIEF DESCRIPTION OF THE DRAWINGS

FIG. 1 is a block diagram schematically illustrating a configuration of a fractional-N PLL frequency synthesizer according to a first embodiment of the disclosure;

FIG. 2 is a block diagram schematically illustrating a configuration of a delta sigma modulator 107 and a controlling unit 108 in FIG. 1;

FIG. 3 is a circuit diagram schematically illustrating a configuration of a CPDAC 102 in FIG. 1;

FIG. 4 is a timing chart for describing an instantaneous phase error compensating operation in a fractional-N PLL frequency synthesizer in FIG. 1;

FIG. 5 is an explanatory diagram and an extraction from part of FIG. 2, for describing an offset value to be given to a phase error signal PE in FIG. 2;

FIG. 6 is a timing chart when fractional data of division ratio data of a fractional-N PLL frequency synthesizer in FIG. 1 is zero, that is, when an integer-N operation is performed;

FIG. 7 is a graph for describing input/output characteristics of a phase comparator 101 in FIG. 1;

FIG. 8 is a graph for describing a system simulation results of SSB phase noise characteristics by a fractional-N PLL frequency synthesizer in FIG. 1;

FIG. 9 is a block diagram schematically illustrating a configuration of a controlling unit in a fractional-N PLL frequency synthesizer according to a second embodiment of the disclosure;

FIG. 10 is a block diagram schematically illustrating a configuration of a CPDAC in a fractional-N PLL frequency synthesizer according to a third embodiment of the disclosure;

FIG. 11 is a block diagram schematically illustrating a configuration of a wireless communication apparatus according to a fourth embodiment of the disclosure;

FIG. 12 is a block diagram schematically illustrating a configuration of a fractional-N PLL frequency synthesizer in the related art disclosed in U.S. Pat. No. 6,960,947;

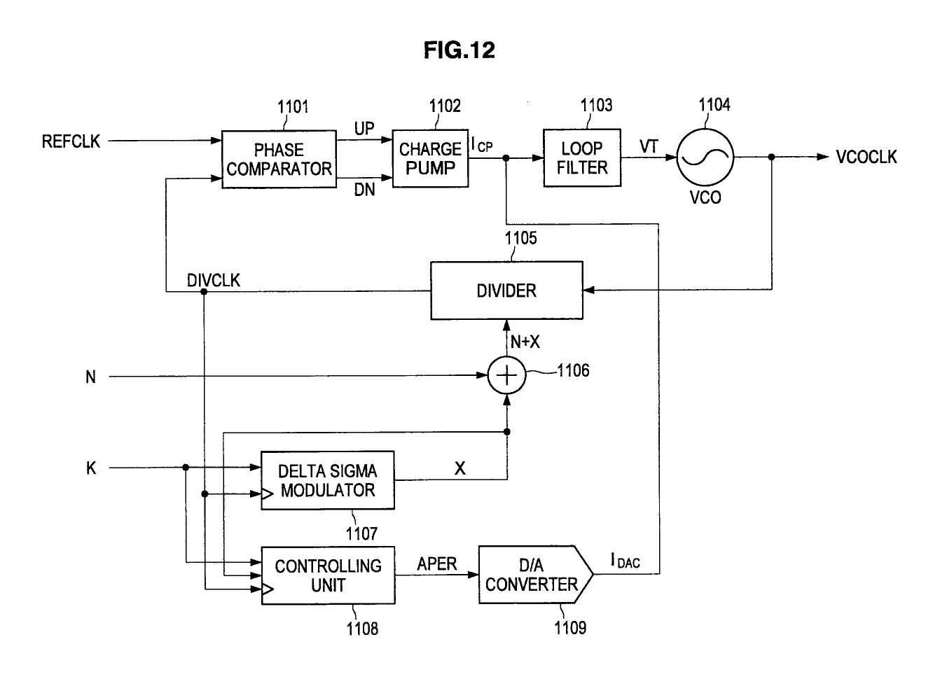

FIG. 13 is a block diagram schematically illustrating a configuration of a phase comparator including a charge pump disclosed in U.S. Pat. No. 4,970,475; and

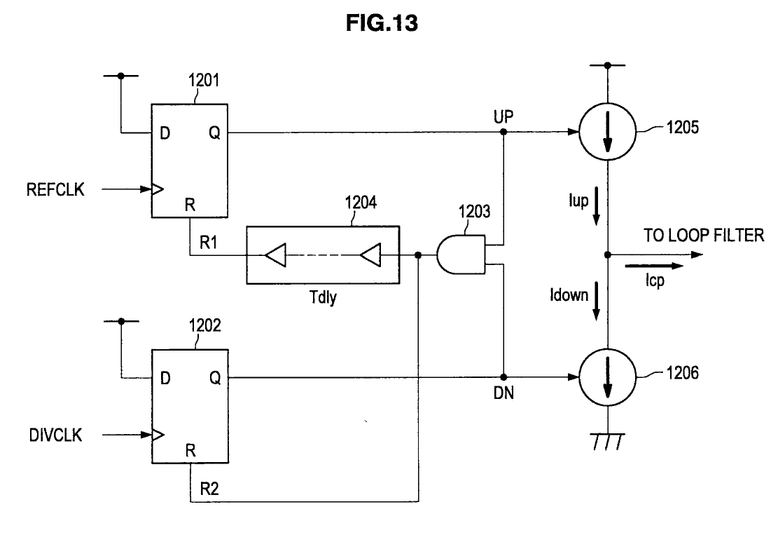

FIG. 14 is a timing chart of each signal in the phase comparator in FIG. 13.

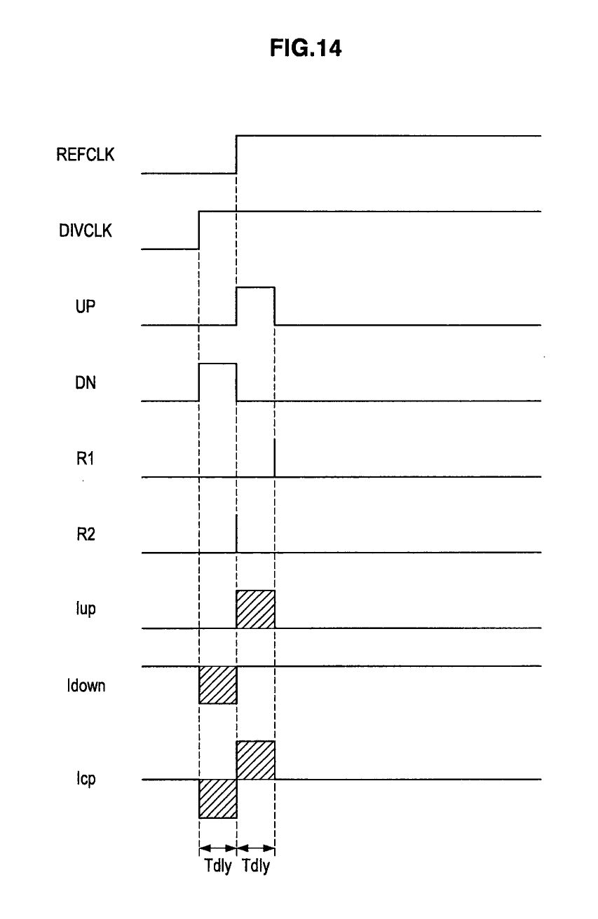

### DETAILED DESCRIPTION OF THE EMBODIMENTS

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that description will be provided in the following order.

1. First Embodiment

2. Second Embodiment

3. Third Embodiment

4. Fourth Embodiment

5. Conclusion

### 1. First Embodiment

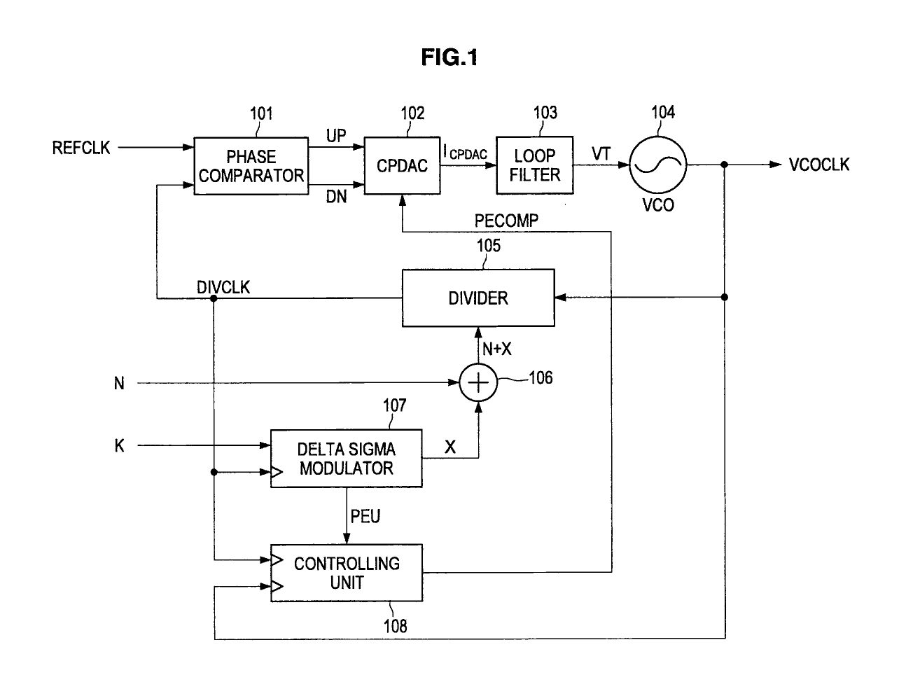

First, a fractional-N PLL frequency synthesizer according to the first embodiment of the disclosure will be described. FIG. 1 is a block diagram schematically illustrating a configuration of the fractional-N PLL frequency synthesizer according to the present embodiment.

In FIG. 1, a reference frequency signal REFCLK is input to a phase comparator 101. The phase comparator 101 is an example of a phase comparing unit of the disclosure, and compares the phase of a division signal DIVCLK obtained by dividing an output signal VCOCLK of a voltage controlling oscillator (VCO) 104 of a later stage by N by means of a divider 105 and the phase of a reference frequency signal REFCLK. When the phase (edge) of the reference frequency signal REFCLK is preceding, an UP signal output of the phase comparator 101 is a high level until the phase (edge) of the delaying division signal DIVCLK arrives. When the phase (edge) of the division signal (DIVCLK) arrives, the phase comparator 101 is reset, and the UP signal output becomes a low level. When the phase (edge) of the division signal (DIVCLK) is preceding, a DN (down) signal output of the phase comparator 101 is a high level until the phase (edge) of a delaying reference frequency signal REFCLK arrives. When the phase (edge) of the reference frequency signal REFCLK arrives, the phase comparator 101 is reset and the DN signal output becomes a low level. The signal output from the phase comparator 101 is output to a CPDAC 102.

The CPDAC 102 is an example of a current pulse signal generating unit of the disclosure and is a circuit which combines a function of a charge pump and a function of a D/A (digital/analog) converter, and causes an inflow or outflow of a current matching the UP signal and DN signal from the phase comparator 101 and a phase error compensation signal PECOMP from the controlling unit 108 to generate a current pulse signal I_{CPDAC} proportional to the phase difference. The current pulse signal I_{CPDAC} of the CPDAC 102 is output to the loop filter 103.

The loop filter 103 is an example of a converting unit of the disclosure, and integrates, smoothes and converts the current pulse signal I_{CPDAC} of the CPDAC 102 into a voltage signal. The output voltage signal VT of this loop filter 103 is a control voltage of the VCO 104.

The VCO 104 is an example of an outputting unit of the disclosure, and outputs a signal VCOCLK having an oscillation frequency matching the output voltage signal VT from the loop filter 103. This output signal VCOCLK is output to a configuration (for example, a frequency converter) in a later stage (not illustrated) as an output signal of the fractional-N PLL frequency synthesizer, and is divided by the divider 105 and then is fed back to the phase comparator 101.

The delta sigma modulator 107 integrates and quantizes fractional data K of the division ratio for fractional-N which is supplied from a data supplying means such as a register (not illustrated) and outputs an output signal X to the adder 106. The output signal X of the delta sigma modulator 107 is a sequence represented by a pseudo random integer where an average value of the output signal X is equal to an input value K/M (M is the bit depth of K), and a sequence pattern is determined based on an order, bit width and input value of the delta sigma modulator 107. The adder 106 adds the output signal X of the delta sigma modulator 107 to integer data N of the division ratio supplied from the data supplying means, and supplies the division ratio control signal N+X to the divider 105. That is, the division ratio control signal N+X is a pseudo random integer sequence where the average value is equal to N+K/M. The delta sigma modulator 107 and adder 106 are examples of a division ratio control signal generating unit of the disclosure.

The divider 105 is an example of a dividing unit of the disclosure and is a programmable divider which can adopt a plurality of division ratios according to supplied data, and receives the modulated division ratio control signal N+X and divides the output signal VCOCLK at a division ratio matching the division ratio control signal N+X.

Thus, the fractional-N PLL frequency synthesizer illustrated in FIG. 1 modulates the divider 105 which divides the output of the VCO 104 according to an output signal of the delta sigma modulator 107 to realize fractional-N on average.

With a fractional-N PLL frequency synthesizer, although the phase of the reference frequency signal REFCLK and the phase of the division signal DIVCLK match in the phase comparator 101 on average, both the phases do not completely match.

Quantization noise output from the delta sigma modulator 107 is determined based on the order, bit width and input value, so that it is possible to predict and compensate for the instantaneous phase error produced in the phase comparator 101. The instantaneous phase error is calculated according to the following equation 2 when the cycle of the output signal VCOCLK is 2#.

$$Δ φ [ n ] = Δ φ [ n - 1 ] + 2 \cdot π ( \frac{K - M \cdot X [ n ]}{M} ) \qquad equation 2$$

Here, n is a natural number, K is fractional data of the division ratio, M is the bit depth of the fractional data K and X is an output signal of the delta sigma modulator 107.

Based on the above equation 2, the delta sigma modulator 107 integrates the difference between the fractional data K and the output signal X of the delta sigma modulator 107 and scales this difference using the bit depth M of the fractional data K or performs a method of acquiring an equivalent result to generate and supply a phase error signal PEU to the controlling unit 108. The bit depth M is power of two, so that division using M can be realized as bit shifting in a logical circuit and hardware added for this division is substantially unnecessary.

The phase error signal PEU input to the controlling unit 108 is decomposed to at least two portions, each is shaped in a pulse signal having the time width equal to the cycle of the VCO 104 and is output to the CPDAC 102 sequentially or at different timings after some time intervals as a phase error compensation signal PECOMP. The controlling unit 108 is an example of the phase error compensation signal generating unit of the disclosure.

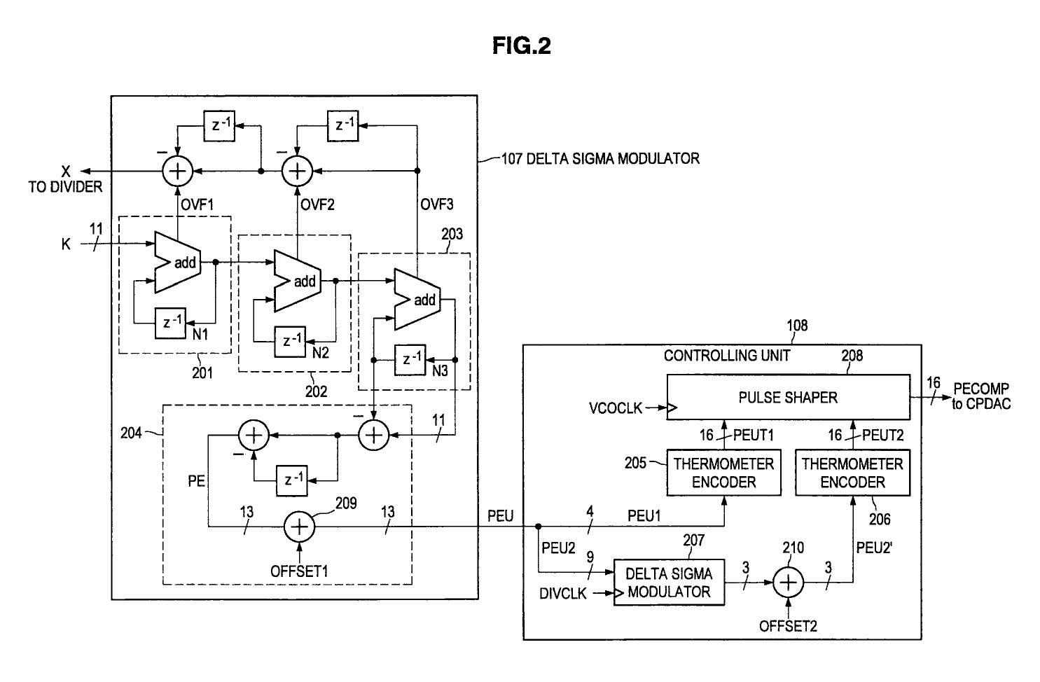

Next, the delta sigma modulator 107 and controlling unit 108 in FIG. 1 will be described in detail. FIG. 2 is a block diagram schematically illustrating a configuration of the delta sigma modulator 107 and controlling unit 108 in FIG. 1.

In FIG. 2, the delta sigma modulator 107 employs, for example, a configuration which is referred to as “1-1-1MASH (MultisTage noise SHaping)”. While a first accumulation adder 201 accumulates input data K and outputs an overflow signal OVF1, the first accumulation adder 201 supplies the residual, that is, quantization noise N1, to a second accumulation adder 202. While the second accumulation adder 202 accumulates quantization noise N1 of the first accumulation adder 201 and outputs an overflow signal OVF2, the second accumulation adder 202 supplies quantization noise N2 to a third accumulation adder 203. The third accumulation adder 203 accumulates quantization noise N2 of the second accumulation adder 202 and outputs an overflow signal OVF3. The overflow signals OVF1, OVF2 and OVF3 of the first accumulation adder 201, second accumulation adder 202 and third accumulation adder 203 are subjected to difference and addition processing, and supplied to the divider 105 in FIG. 1 as the output signal X. The transfer function from the input data K to the output signal X is calculated according to the following equation 3.

X(z)=K(z)+(1−z⁻¹)³·N₃(z) equation 3

According to the above equation 3, the input data K passes without being influenced, and quantization noise is subjected to third-order noise shaping. The quantization noise N1 added by the first accumulation adder 201 and the quantization noise N2 added by the second accumulation adder 202 are cancelled in the process of difference and addition processing of the overflow signals, and noise appearing in the output signal X is caused only by the quantization noise N3 added by the third accumulation adder 203.

The following equation 4 holds when the above equation 2 is rewritten as a conversion equation for z and the above equation 3 is substituted in this equation.

$$\begin{matrix}PE ( z ) = {z}^{- 1} \cdot PE ( z ) + \frac{K ( z )}{M} - X ( z ) \\ = {z}^{- 1} \cdot PE ( z ) + \frac{K ( z )}{M} - \\ \{ \frac{K ( z )}{M} + {( 1 - {z}^{- 1} )}^{3} \cdot {N}_{3} ( z ) \} \\ = {z}^{- 1} \cdot PE ( z ) - {( 1 - {z}^{- 1} )}^{3} \cdot {N}_{3} ( z )\end{matrix} \qquad equation 4$$

Here, PE is a phase error, K is fractional data of the division ratio, M is the bit depth of the fractional data K and N is integer data of the division ratio.

The following equation 5 holds when the above equation 4 is solved in terms of PE(z).

PE(z)=−(1−z⁻¹)²·N₃(z) equation 5

That is, the phase error PE can be obtained by finding the second difference of the quantization noise N3 of the third accumulation adder 203. As described with the phase error signal generating circuit 204, the delay circuit of the third accumulation adder 203 can be utilized as part of the second difference circuit, so that it is possible to realize a desired operation by adding a small-scale circuit. The phase error signal generating circuit 204 adds a predetermined offset value OFFSET1 to the phase error PE and supplies the phase error signal PEU to the controlling unit 108.

The phase error signal PEU input to the controlling unit 108 is divided into an upper bit signal PEU1 and lower bit signal PEU2, and the upper bit signal PEU1 is supplied to a first thermometer encoder 205 and the lower bit signal PEU2 is supplied to a delta sigma modulator 207. The lower bit signal PEU2 is processed in the delta sigma modulator 207, is added a predetermined offset value OFFSET2 and is supplied to a second thermometer encoder 206 as a signal PEU2′. The signal PEU1 and signal PEU2′ are examples of phase error compensation data of the disclosure.

The first thermometer encoder 205 converts the input signal PEU1 having binary code into a signal PEUT1 of a thermometer code to supply to a pulse shaper 208. The second thermometer encoder 206 converts the input signal PEU2′ having binary code into a signal PEUT2 of a thermometer code to supply to the pulse shaper 208. The first thermometer encoder 205 and second thermometer encoder 206 are examples of a thermometer code converting unit of the disclosure.

The pulse shaper 208 shapes the input signal PEUT1 and signal PEUT2 in pulse signals having the time width equal to the cycle of the VCO 104, to output to the CPDAC 102 in FIG. 1 sequentially or at different timings after some time intervals as a phase error compensation signal PECOMP.

In addition, the pulse width of the phase error compensation signal PECOMP may be equal to the clock cycle obtained by dividing the output of the VCO 104 by an integer. In this case, the scaling amount in the above equation 2 needs to be changed. The integer division ratio is preferably power of 2 to enable simple scaling using bit shifting.

In addition, a configuration may be employed where the first thermometer encoder 205 and second thermometer encoder 206 are provided at a later stage of the pulse shaper 208 or inside the CPDAC 102.

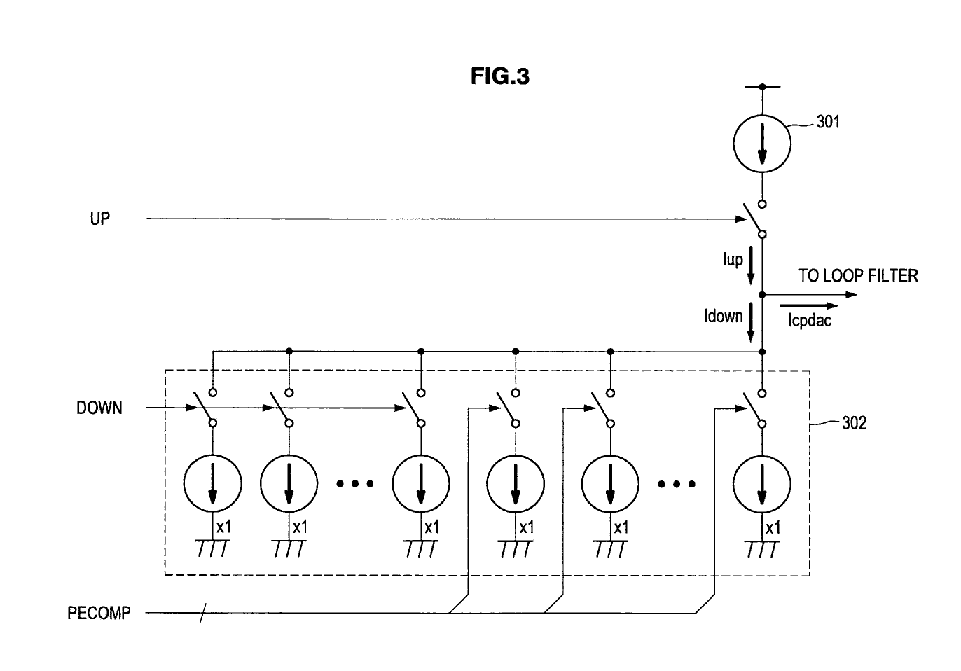

Next, the CPDAC 102 in FIG. 1 will be described in detail. FIG. 3 is a circuit diagram schematically illustrating a configuration of the CPDAC 102 in FIG. 1.

In FIG. 3, the CPDAC 102 has, for example, a UP current cell 301 which is connected between a power source and loop filter output terminal and which receives an UP signal from the phase comparator 101 and outputs the current pulse signal Iup, and a DN current cell array 302 which is connected between a ground potential and loop filter output terminal and which receives a DN signal from the phase comparator 101 or a phase error compensation signal PECOMP from the controlling unit 108 to output the current pulse signal Idown.

The DN current cell array 302 has a plurality of unitary current cells, and part of unitary current cells are controlled according to the DN signal from the phase comparator 101 and part of unitary current cells are controlled according to the phase error compensation signal PECOMP from the controlling unit 108. Consequently, it is possible to improve the linearity of the phase error compensating operation and improve matching between an operating current according to the DN signal and an operating current according to the phase error compensating operation.

Further, a bias circuit (not illustrated) which generates a bias voltage given to the UP current cell 301 and DN current cell array 302 preferably has a unit which improves matching between the UP current cell 301 and DN current cell array 302.

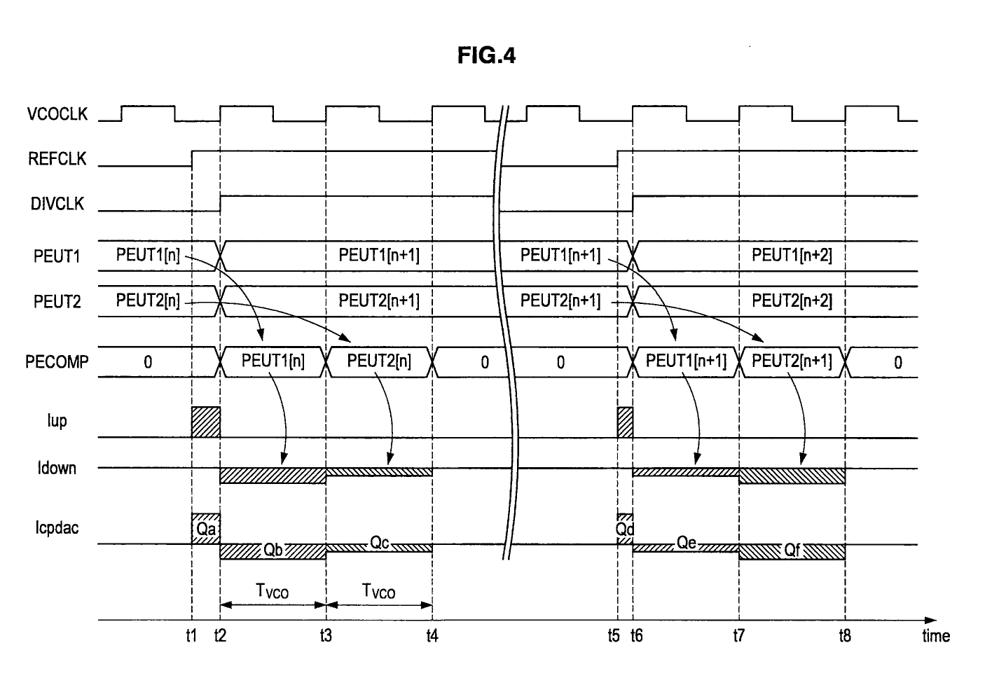

Next, the instantaneous phase error compensating operation in the fractional-N PLL frequency synthesizer in FIG. 1 will be described. FIG. 4 is a timing chart for describing the instantaneous phase error compensating operation in the fractional-N PLL frequency synthesizer in FIG. 1.

In FIG. 4, the UP current cell 301 of the CPDAC 102 outputs to the loop filter 103 the current pulse signal Iup in a period between a time t1 and time t2 which correspond to the phase difference between the reference frequency signal REFCLK and division signal DIVCLK.

The pulse shaper 208 of the controlling unit 108 outputs to the CPDAC 102 the output signal PEUT1 of the first thermometer encoder 205 as the phase error compensation signal PECOMP in a period between the time t2 of the edge of the division signal DIVCLK and a time t3 of the next edge of the VCOCLK. Similarly, the pulse shaper 208 outputs to the CPDAC 102 the output signal PEUT2 of the second thermometer encoder 206 as the phase error compensation signal PECOMP in a period between the time t3 and a time t4 of the next edge of the VCOCLK. In a period up to the time t5 when the next edge of the reference frequency signal REFCLK arrives after the time t4, no phase error compensation signal PECOMP is output. The DN current cell array 302 of the CPDAC 102 outputs the current pulse signal Idown to the loop filter 103 in response to the phase error compensation signal PECOMP.

The loop filter 103 receives a supply of a current pulse signal Icpdac which is the sum of the current pulse signal Iup and current pulse signal Idown. The charge amount Qa supplied in a period between the time t1 and t2 according to the current pulse signal Icpdac is nearly equal to the charge amount Qb supplied in a period between the time t2 and time t3. Meanwhile, the charge amount Qa includes a truncation error produced when the upper bit signal PEU1 is extracted from the phase error signal PEU in the controlling unit 108. Hence, the total charge amount supplied to the loop filter 103 in a period between the time t1 and time t3 is equal to the truncation error. The truncation error in the charge amount Qc supplied in a period between the time t3 and time t4 is subjected to noise shaping in a high frequency area.

Also in the period between the time t5 and time t8, the charge amount Qd supplied in a period between the time t5 and time t6 according to the current pulse signal Icpdac is nearly equal to the charge amount Qe supplied in a period between the time t6 and time t7. The truncation error in the charge amount Qf supplied in a period between the time t7 and time t8 is subjected to noise shaping in a high frequency area.

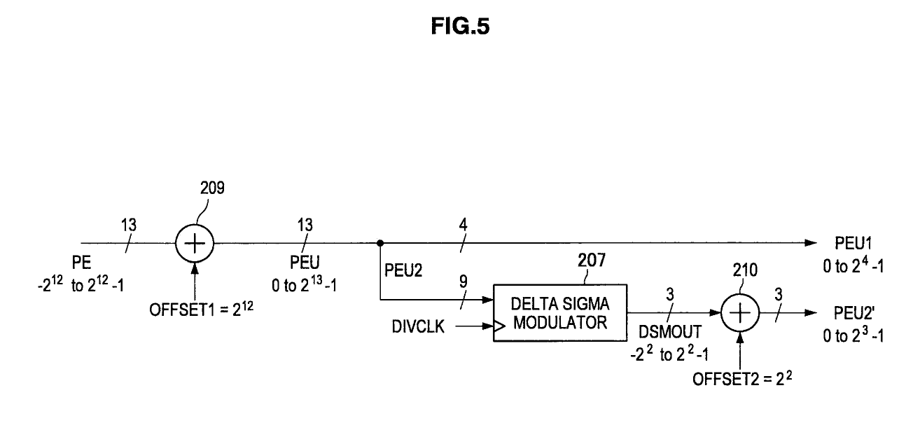

Next, an offset value given to a phase error signal PE in FIG. 2 will be described. FIG. 5 is an explanatory diagram and an extraction from part of FIG. 2, for describing an offset value to be given to a phase error signal PE in FIG. 2.

In FIG. 5, when the bit width of the third accumulation adder 203 is 11 bits, the phase error signal PE obtained by finding the second difference of quantization noise N3 of the third accumulation adder 203 has the bit width of 13 bits, and the values adopt a range between −2¹² and 2¹²−1 by complement representation of 2. The adder 209 adds a predetermined offset value OFFSET1=2¹² to the above phase error signal PE. By this means, the phase error signal PEU which is the output of the adder 209 becomes single polarity data which adopts the range between 0 and 2¹³−1. The lower bit signal PEU2 of the phase error signal PEU which is the output of the adder 209 is processed by the delta sigma modulator 207. When the delta sigma modulator 207 employs, for example, a 1-1-1MASH configuration, the output signal DSMOUT adopts the range between −2² and 2²−1 by complement representation of 2. The adder 210 adds a predetermined offset value OFF SET2=2² to the output signal DSMOUT of the delta sigma modulator 207. By this means, the signal PEU2′ which is the output of the adder 210 becomes single polarity data which adopts the range between 0 and 2³−1.

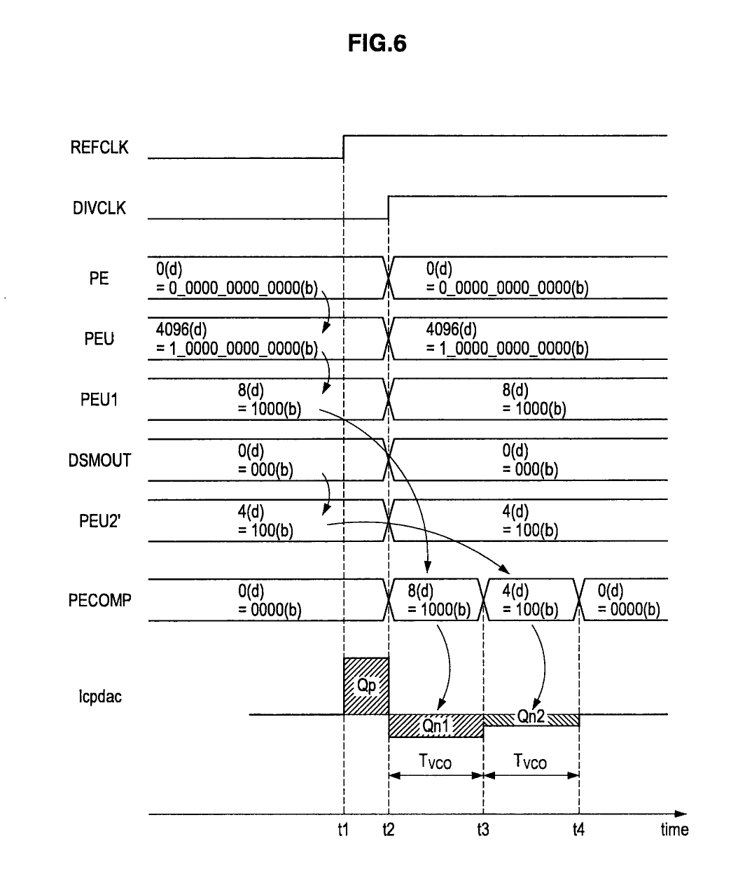

Next, the effect obtained by adding the offset value OFFSET1 and offset value OFFSET2 will be described with reference to FIG. 6. FIG. 6 is a timing chart when fractional data of division ratio data of the fractional-N PLL frequency synthesizer in FIG. 1 is zero, that is, when an integer-N operation is performed.

In FIG. 6, the fractional data is zero, and therefore the delta sigma modulator 107 keeps outputting zero. Accordingly, the phase error PE calculated according to the above equation 5 is also zero. In FIG. 6, numerical values with (d) added to the ends are decimal representation and with (b) added to the ends are binary representation. OFFSET1=4096(d) (fixed value) is added in the adder 209 to obtain a phase error signal PEU=4096(d). Hence, the signal PEU1=8(d) extracting upper four bits of the phase error signal PEU is obtained. The lower bit signal PEU2 of the phase error signal PEU is zero, and therefore the output signal DSMOUT of the delta sigma modulator 207 is zero and OFFSET2=4(d) (fixed value) is added in the adder 210 to obtain PEU2′=4(d). The pulse shaper 208 outputs the signal PEU1 and signal PEU2′ as the phase error compensation signal PECOMP at a predetermined time, and the CPDAC 102 outputs a current pulse matching the phase error compensation signal PECOMP. In addition, according to the configuration of FIG. 2, although the phase error compensation signal PECOMP is data represented by thermometer code, the phase error compensation signal PECOMP is represented by binary code in FIG. 6 for ease of description. The adder 209 and the adder 210 are examples of an adding unit of the disclosure.

As described above, by adding the offset value OFFSET1 or offset value OFFSET2 in process of generating the phase error compensation signal PECOMP from the phase error PE, it is possible to perform a phase error compensating operation using a single polarity. By this means, a current cell array of the CPDAC 102 related to the phase error compensating operation can be configured using a single unitary cell, so that it is possible to provide a good linearity.

Further, the PLL circuit is locked to the phase difference in the stationary state of a loop such that the sum of the charge amount Qn1 supplied in the period between the time t2 and time t3 and the charge amount Qn2 supplied in the period between time t3 and time t4 is equal to the charge amount Qp supplied in the period between the time t1 and time t2. This means that the operation point of the phase comparator 101 is shifted to a linear area.

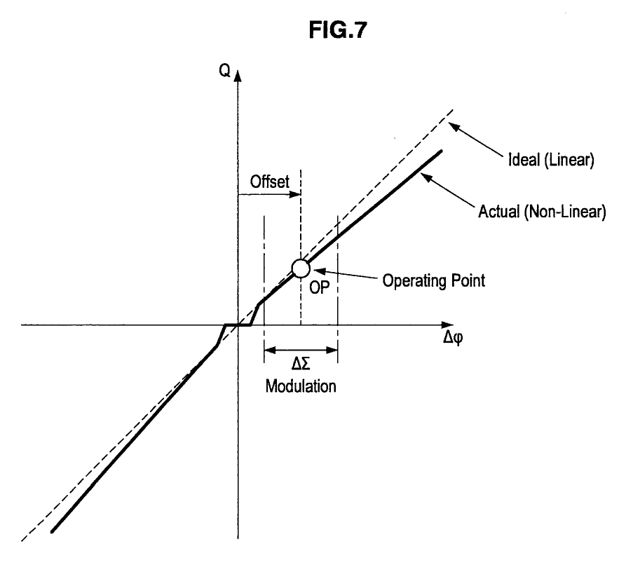

Further, the effect obtained by adding the offset value OFFSET1 and offset value OFFSET2 will be described with reference to FIG. 7. FIG. 7 is a graph for describing input/output characteristics of the phase comparator 101 in FIG. 1.

In FIG. 7, the horizontal axis indicates the phase difference between the reference frequency signal REFCLK and division signal DIVCLK input to the phase comparator 101, in which the state where the reference frequency signal REFCLK precedes is positive. The vertical axis indicates the charge amount output from the CPDAC 102. Ideally, although linear characteristics indicated by the broken line are preferably obtained, non-linear characteristics indicated by the solid line are actually obtained. The above effect of the offset value OFFSET1 or offset value OFFSET2 of the phase error compensation signal PECOMP locks the PLL circuit according to the present embodiment to the operation point OP illustrated in FIG. 7. In FIG. 5, the offset value OFFSET1 added in the adder 209 among offset values to be added to the phase error compensation signal PECOMP is half the dynamic range of the phase error produced by the fractional-N operation, and, fundamentally, is the minimum necessary amount as the offset amount for preventing the phase error produced by the fractional-N operation from crossing the original point of input/output characteristics of the phase comparator 101. As shown in FIG. 7, the non-linear area of input/output characteristics of the phase comparator 101 actually has a certain width near the original point. This can be avoided by adding the offset value OFFSET2 in the adder 210 and further shifting the operation point of the phase comparator 101.

As described above, by giving the offset value OFFSET1 or offset value OFFSET2 to the phase error compensation signal PECOMP, it is possible to shift the operation point of the phase comparator 101 to a linear area without adding new hardware and provide good noise performance.

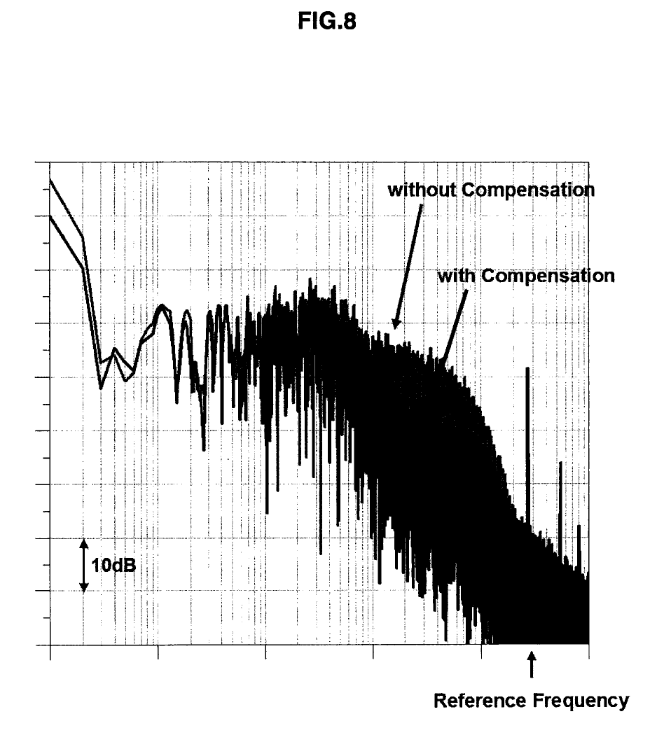

Next, a system simulation results of SSB (single side band) phase noise characteristics by a fractional-N PLL frequency synthesizer in FIG. 1 will be described. FIG. 8 is a graph for describing the system simulation results of SSB phase noise characteristics by the fractional-N PLL frequency synthesizer in FIG. 1. In FIG. 8, the result that the phase error compensation function is operated and the result that this function is not operated are overlapped. The simulation results include jitter of the phase comparator 101, current noise of the CPDAC 102, mismatch between current cells of the CPDAC 102, resistance noise of the loop filter 103 and phase noise of the VCO 104.

The simulation results show that quantization noise of the delta sigma modulator appearing outside the loop band is effectively suppressed by the phase error compensation function.

### 2. Second Embodiment

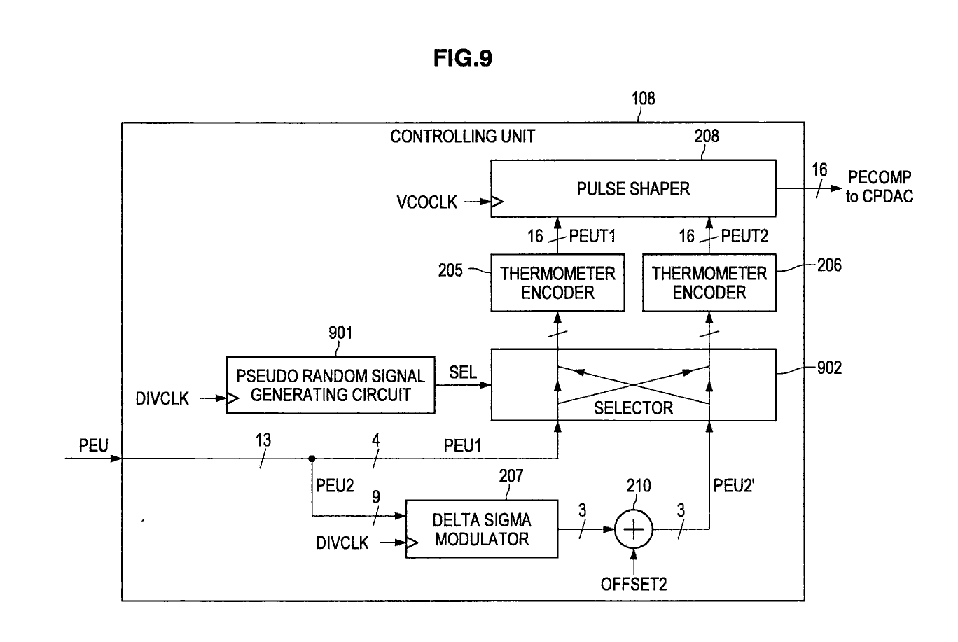

Next, a fractional-N PLL frequency synthesizer according to the second embodiment of the disclosure will be described. FIG. 9 is a block diagram schematically illustrating a configuration of a controlling unit in a fractional-N PLL frequency synthesizer according to the present embodiment. The fractional-N PLL frequency synthesizer according to the present embodiment differs from the above first embodiment in that the controlling unit 108 further has a pseudo random signal generating circuit 901 and a selector 902.

In FIG. 9, the pseudo random signal generating circuit 901 is driven according to the division signal DIVCLK and generates a pseudo random signal SEL. The selector 902 switches a supply destination of the signal PEU1 and signal PEU2′ between the first thermometer encoder 205 and second thermometer encoder 206 based on the pseudo random signal SEL. For example, when the pseudo random signal SEL is at a low level, the signal PEU1 is supplied to the first thermometer encoder 205 and the signal PEU2′ is supplied to the second thermometer encoder 206 and, when the pseudo random signal SEL is at a high level, the signal PEU1 is supplied to the second thermometer encoder 206 and the signal PEU2′ is supplied to the first thermometer encoder 205. The pseudo random signal generating circuit 901 and selector 902 are examples of a randomizing unit of the disclosure.

That is, in the phase error compensation signal PECOMP output from the pulse shaper 208 to the CPDAC 102, the order to supply information related to upper bits of the phase error signal PEU and information related to lower bits changes pseudo-randomly. That is, the order to use phase error compensation data is randomized. As a result, it is possible to reduce a spurious level which occurs in a specific division ratio setting.

In addition, various changes can be made according to the design within a range which does not deviate from the technical idea of the disclosure by, for example, providing a randomizing unit in the pulse shaper 208.

### 3. Third Embodiment

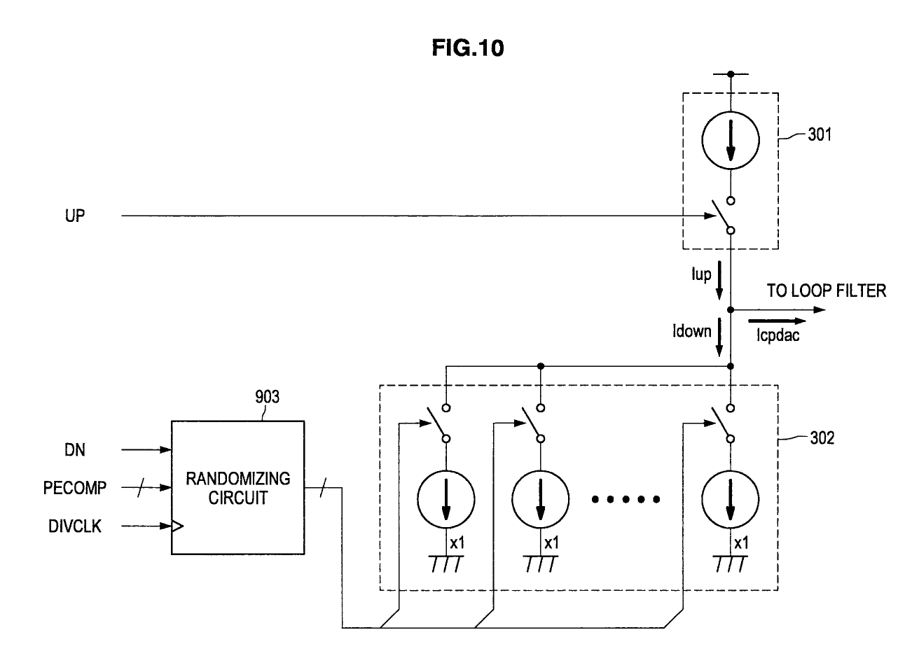

Next, a fractional-N PLL frequency synthesizer according to the third embodiment of the disclosure will be described. FIG. 10 is a block diagram schematically illustrating a configuration of a CPDAC in the fractional-N PLL frequency synthesizer according to the present embodiment. The fractional-N PLL frequency synthesizer according to the present embodiment differs from the above first embodiment in that the CPDAC 102 further has a randomizing circuit 903.

In FIG. 10, the randomizing circuit 903 is driven according to a division signal DIVCLK, and changes at random a unitary current cell used by a DN signal and phase error compensation signal PECOMP per phase comparison. By this means, it is possible to further improve matching between the operation current of the DN signal and the operation current of the phase error compensating operation.

### 4. Fourth Embodiment

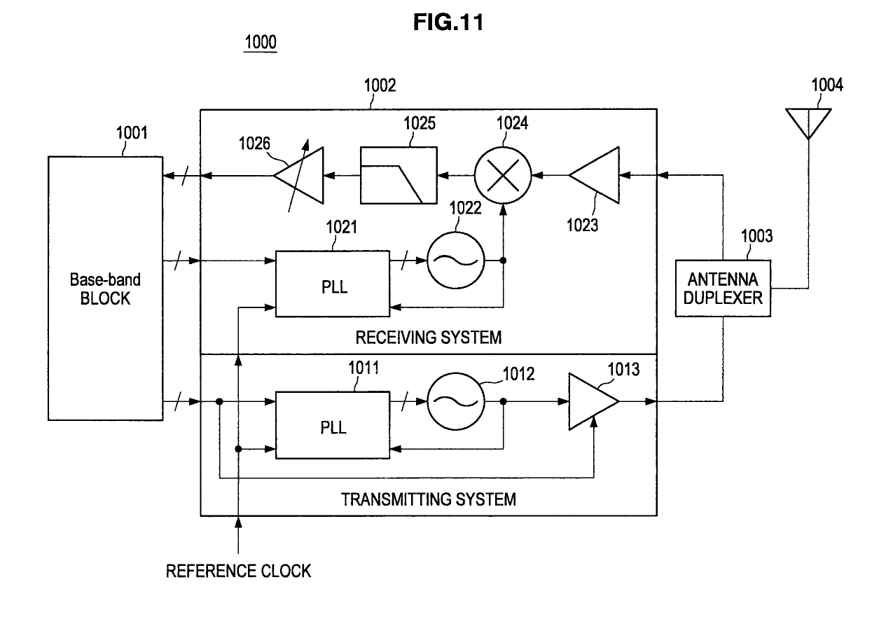

Next, a wireless communication apparatus according to the fourth embodiment of the disclosure will be described. FIG. 11 is a block diagram schematically illustrating a configuration of the wireless communication apparatus according to the fourth embodiment of the disclosure.

In FIG. 11, a wireless communication apparatus 1000 has a base-band block 1001, a transmitting/receiving module 1002, an antenna duplexer 1003 and an antenna 1004 which transmits and receives radio waves.

The base-band block 1001 handles a base-band signal, and transmits and receives signals to and from the transmitting/receiving module 1002. The transmitting/receiving module 1002 performs signal processing of transmitting and receiving signals to and from the base-band block 1001. The antenna duplexes 1003 transmits and receives signals to and from the transmitting/receiving module 1002. The antenna 1004 transmits and receives radio waves.

Further, the transmitting/receiving module 1002 is divided into a transmitting system and a receiving system, and the transmitting system has a PLL 1011, an oscillator 1012 and an amplifier 1013 and the receiving system has a PLL 1021, an oscillator 1022, an amplifier 1023, a down-converter 1024, a lowpass filter 1025 and a variable gain converter 1026.

One of the fractional-N PLL frequency synthesizers according to the above first to third embodiments of the disclosure is applicable to the PLLs 1011 and 1021 illustrated in FIG. 11. By applying one of the fractional-N PLL frequency synthesizers according to the above first to third embodiments of the disclosure to the wireless communication apparatus 1000, the wireless communication apparatus 1000 can provide the above effect of each embodiment.

In addition, the configuration of the wireless communication apparatus 1000 illustrated in FIG. 11 is one example, and is by no means limited to this example. As long as an apparatus uses a PLL, the fractional-N PLL frequency synthesizer according to each embodiment of the disclosure is applicable to this apparatus.

### 5. Conclusion

According to each of the above embodiments, mounting of a divider becomes unnecessary by shaping the phase error compensation signal PECOMP in a pulse shape having the cycle of VCOCLK or the time width related to the cycle of VCOCLK. Further, by shaping the phase error compensation signal PECOMP in a pulse shape having the cycle of VCOCLK or the time width related to the cycle of VCOCLK, it is possible to relax the demand for resolution of a current cell array necessary for phase error compensation. Furthermore, by shaping the phase error compensation signal PECOMP in a pulse shape having the cycle of VCOCLK or the time width related to the cycle of VCOCLK, it is possible to provide loop design which reduces a charge pump current and reduces capacity of the loop filter 103, and mount the loop filter 103 on an integrated circuit.

Further, according to each of the above embodiments, a configuration is employed which decomposes the phase error signal PE into at least two portions, shapes each portion into a pulse signal having the time width equal to the cycle of the VCO 104 and outputs the signal as the phase error compensation signal PECOMP to the CPDAC 102 sequentially or at different timings after time intervals, so that it is possible to reduce a current cell necessary for a phase error compensating operation and reduce the influence due to non-linearity of an analog circuit.

Still further, according to each of the above embodiments, by adding an offset to the phase error compensation signal PECOMP, the phase error compensating operation can be realized with a single polarity, so that it is possible to provide a good linearity. Moreover, by adding an offset to the phase error compensation signal PECOMP, it is possible to shift the operation point of the phase comparator 101 to a linear area of input/output characteristics of the phase comparator 101, and provide good phase noise performance. Further, by adding an offset to the phase error compensation signal PECOMP, delay at a gate is not utilized, so that it is possible to reduce the influence of jitter. Furthermore, by adding an offset to the phase error compensation signal PECOMP, the offset to be given is the minimum necessary offset amount to shift the desired operation point, so that it is possible to reduce an increase of reference spurious. Still further, by adding an offset to the phase error compensation signal PECOMP, the influence of process variation, temperature and voltage power source on the operation point shift amount is little, so that it is possible to stably provide good phase noise performance.

Moreover, according to the above second embodiment, by changing the order to supply at least two phase error compensation signals PECOMP to the CPDAC 102 according to a pseudo random signal, it is possible to reduce a spurious level which occurs in a specific division ratio setting.

Further, according to the above third embodiment, by changing a unitary current cell used by a DN signal and phase error compensation signal PECOMP at random per phase comparison, it is possible to further improve matching between the operation current of the DN signal and the operation current of the phase error compensating operation.

Although preferred embodiments of the disclosure are described in detail above with reference to the appended drawings, the disclosure is not limited thereto. It should be understood by those skilled in the art that various modifications, combinations, sub-combinations and alterations may occur depending on design requirements and other factors insofar as they are within the scope of the appended claims or the equivalents thereof.

The present disclosure contains subject matter related to that disclosed in Japanese Priority Patent Application JP 2010-180316 filed in the Japan Patent Office on Aug. 11, 2010, the entire content of which is hereby incorporated by reference.

What is claimed is:

1. A PLL frequency synthesizer comprising:
a phase comparing unit which compares a phase of a reference frequency signal and a phase of a division signal;
a current pulse signal generating unit which generates a current pulse signal according to a signal from the phase comparing unit and a phase error compensation signal from a phase error compensation signal generating unit;
an converting unit which converts the current pulse signal from the current pulse signal generating unit into a voltage signal;
an outputting unit which outputs a signal of an oscillation frequency matching the voltage signal from the converting unit;
a divider which divides an output from the outputting unit by a division ratio matching a division ratio control signal to output as the division signal;
a division ratio control signal generating unit which generates the division ratio control signal based on division ratio data for fractional-N; and
the phase error compensation signal generating unit which generates at least two items of phase error compensation data from the division ratio data, and generates the phase error compensation signal utilizing the at least two generated items of phase error compensation data at different timings.

2. The PLL frequency synthesizer according to claim 1,
wherein the phase error compensation signal generating unit comprises an adding unit which adds a fixed value to the phase error compensation data.

3. The PLL frequency synthesizer according to claim 1,
wherein the phase error compensation signal generating unit comprises a thermometer code converting unit which converts the phase error compensation data from binary code into thermometer code.

4. The PLL frequency synthesizer according to claim 1,
wherein the phase error compensation signal generating unit comprises a randomizing unit which randomizes an order to use the phase error compensation data.

5. A wireless communication apparatus comprising the PLL frequency synthesizer according to claim 1.

6. A PLL frequency synthesizer controlling method comprising:
comparing a phase of a reference frequency signal and a phase of a division signal;
generating a current pulse signal according to a signal generated in the phase comparing step and a phase error compensation signal generated in a phase error compensation signal generating step;
converting the current pulse signal generated in the current pulse signal generating step into a voltage signal;
outputting a signal of an oscillation frequency according to the voltage signal generated in the converting step;
dividing an output of the outputting step by a division ratio matching a division ratio control signal to output as the division signal;
generating the division ratio control signal based on division ratio data for fractional-N; and
generating at least two items of phase error compensation data from the division ratio data, and generating the phase error compensation signal utilizing the at least two generated items of phase error compensation data at different timings.
